(19) United States
(12) Patent Application Publication
(10) Pub. No.: US 2009/0242900 A1
(43) Pub. Date: Oct. 1, 2009

(54) MEMORY DEVICE AND METHOD OF MANUFACTURING THE SAME

(75) Inventors: Bi Shiou CHIOU, Hsinchu City (TW); Li Chun CHANG, Hsinchu County (TW); Chia Cheng HO, Hsinchu City (TW); Dai Ying LEE, Hsinchu County (TW); Yu Shu SHEN, Chiayi County (TW)

Correspondence Address: MORRIS MANNING MARTIN LLP, 3343 PEACHTREE ROAD, NE, 1600 ATLANTA FINANCIAL CENTER, ATLANTA, GA, 30326, US

(73) Assignee: NATIONAL CHIAO TUNG UNIVERSITY, Hsinchu City (TW)

(21) Appl. No.: 12/197,772

(22) Filed: Aug. 25, 2008

(30) Foreign Application Priority Data
Mar. 26, 2008 (TW) 097110676

(51) Int. Cl. H01L 29/15; H01L 21/20

(52) U.S. Cl. 257/77; 438/382; 257/E21.09; 257/E29.072

(57) ABSTRACT

The invention discloses a memory device and method thereof. The memory device comprises a substrate, an insulator layer, a first conducting layer, a CaCu₃Ti₄O₁₂ resistor layer and a second conducting layer. The insulator layer is formed over the substrate. The first conducting layer is formed over the insulator layer. The CaCu₃Ti₄O₁₂ resistor layer is formed over the first conducting layer. The second conducting layer is formed over the CaCu₃Ti₄O₁₂ resistor layer. In manufacturing, firstly, a substrate is provided. Then, a resistor layer is formed on the substrate. Next, a first conducting layer is formed on the resistor layer. Afterward, a CaCu₃Ti₄O₁₂ resistor layer is formed on the first conducting layer by utilizing sol-gel method. Finally, a second conducting layer is formed on the CaCu₃Ti₄O₁₂ resistor layer. The invention not only satisfies a requirement of low driving voltage in electronic product but also increases reliability and compatibility even cost is diminished.

### BACKGROUND OF THE INVENTION

1. Field of the invention

This invention relates to a memory device and a method of manufacturing the same. More particularly, the invention adopts the sol-gel method to manufacture a high quality CaCu₃Ti₄O₁₂ film successfully, and is able to be added various kinds of adequate additives uniformly on it to manufacture the resistor layer of the memory device.

2. Description of the Prior Art

In general, memory devices usually can be classified into two types, i.e., volatile memory and non-volatile memory. The so-called volatile memory is the memory for storing data which must be supplied continuous power to be maintained. Relatively, the non-volatile memory is the memory in which data is stored and can maintain the data for a long even though the power breaks down. For example, both dynamic random access memory (DRAM) and static random access memory (SRAM) which are commonly used in computers are volatile memories, and read-only memory (ROM) is a non-volatile memory.

With the popularization of portable electric devices such as cell phones, digital cameras, PDAs, notebooks, etc., non-volatile memories are broadly applied to various kinds of portable electric devices because of the properties of being able to maintain the memory condition without the power supply and with lower energy consumption during operation. In different kinds of non-volatile memories, flash RAM which can be written in and erased rapidly is paid much attention. But with the miniaturization of devices, the flash RAM also encounters difficulties of excessively large write-in voltage, excessively long write-in time, and the reduction the memory time caused by excessively thin gate electrode. Therefore, many researchers do their best to develop a new non-volatile memory to replace the flash RAM. In all kinds of memories, the resistive non-volatile memory device is paid much attention because of the advantages such as short time for writing and erasing, low voltage and low current during operating, long memory time, multi-state memory, simple structure, simple actions of writing and reading, and a requirement for small area.

Please refer to FIG. 1A. FIG. 1A is a cross-sectional view illustrating a resistive non-volatile memory 1 of a prior art. As shown in FIG. 1A, the resistive non-volatile memory 1 is disposed on the substrate 10 and includes a insulator layer 12, a lower conducting layer 14, a resistor layer 16, and an upper conducting layer 18. Both the lower conducting layer 14 and the upper conducting layer 18 include platinum films. The resistor layer is a film which includes perovskite structure material and has the property of resistance transformation.

Please refer to FIG. 1B. FIG. 1B is a schematic diagram illustrating the relationship between the bias voltage and the leakage current which are applied by the resistive non-volatile memory 1 of the prior art. As shown in FIG. 1B, when the bias voltage which is applied to the resistive non-volatile memory 1 increases from 0, the drain current will increase along with curve C1. But as long as the bias voltage is larger than V_{Set}, the relationship between the drain current and the applied bias voltage will change from curve C1 to curve C2 instantly, so that the drain current will increase instantly. In other words, the resistance value of the resistive non-volatile memory changes from the original high resistance state (R_{HRS}) to low resistance state (R_{LRS}). The relationship between the drain current and the bias voltage will operate according to curve C2 at the low resistance state. Until the bias voltage reaches V_{Reset}, the relationship will turn back to curve C1. That is to say, the resistance value changes from the low resistance value R_{LRS} to the original high resistance value R_{HRS}. Because having the property of achieving resistance transformation by applying DC bias voltage and being able to repetitively operate to obtain the same resistance transformation, memory devices can be fabricated with the resistive non-volatile memory 1.

For example, the two different resistance values can respectively represent 0 and 1. Only by applying an adequate voltage to the resistive non-volatile memory 1, operations such as writing and erasing data in the memory can be achieved by the changing of the resistance value. After the change of the resistance value, the data in the memory will be maintained without power supply.

However, the utilized materials in fabrications of the resistive non-volatile memory device in prior arts are difficult to be disposed. The methods used to grow the resistor layer film usually are vacuum sputtering, metal organic chemical vapor deposition (MOCVD), pulse laser sputtering, etc., whose costs of the utilized materials are high. Moreover, those methods are not suitable for fabricating the films with large area. Thus, the fabrications of prior arts are not suitable for mass production.

Accordingly, the scope of the inventor is to provide a memory device and a method of manufacturing the same to solve the foregoing problems.

### SUMMARY OF THE INVENTION

A scope of the invention is to provide a memory device and the method of manufacturing the same. The invention manufactures the resistor layer of the memory device with a CaCu₃Ti₄O₁₂ film and forms the resistor layer of the resistive memory device by the sol-gel method.

According to a preferred embodiment of the invention, the memory device includes a substrate, an insulator layer, a first conducting layer, a CaCu₃Ti₄O₁₂ resistor layer, and a second conducting layer. The insulator layer is formed on the substrate. The first conducting layer is formed on the insulator layer. The CaCu₃Ti₄O₁₂ resistor layer is formed on the first conducting layer. The second conducting is formed on the resistor layer. While manufacturing, a substrate is provided firstly. Then, an insulator layer is formed on the substrate. As followed, a first conducting layer is formed on the insulator layer. Afterward, a CaCu₃Ti₄O₁₂ resistor layer is formed on the first conducting layer by utilizing sol-gel method. Finally, a second conducting layer is formed on the CaCu₃Ti₄O₁₂ resistor layer.

Compared with the prior art, the memory device provided by the invention takes the CaCu₃Ti₄O₁₂ film as the material of resistor layers. The switching voltage of the material is lower than that of the resistor layer of general resistive memory devices which comply with the requirement of low voltage toward general electric products. Besides, the invention adopts sol-gel method to form the resistor layer, which not only has advantages of low cost and easy control method, but also is appropriate to manufacture films with large area. Because of having the higher compatibility than the general semiconductor methods, the invention can save the costs and promote the reliability of products at the same time. Moreover, the ratio of the switching voltage and the resistance value can be adjusted after utilizing different electrode material, so as to prompt the electrical performance of memory devices and meet requirements of practice utility.

The advantage and spirit of the invention may be understood by the following recitations together with the appended drawings.

### BRIEF DESCRIPTION OF THE APPENDED DRAWINGS

FIG. 1A is a cross-sectional view illustrating an optical fiber device according to an embodiment of the invention.

FIG. 2 is a cross-sectional view illustrating an optical fiber device according to another embodiment of the invention.

FIG. 3 is a flow chart showing a method of optical fiber inspection method according to an embodiment of the invention.

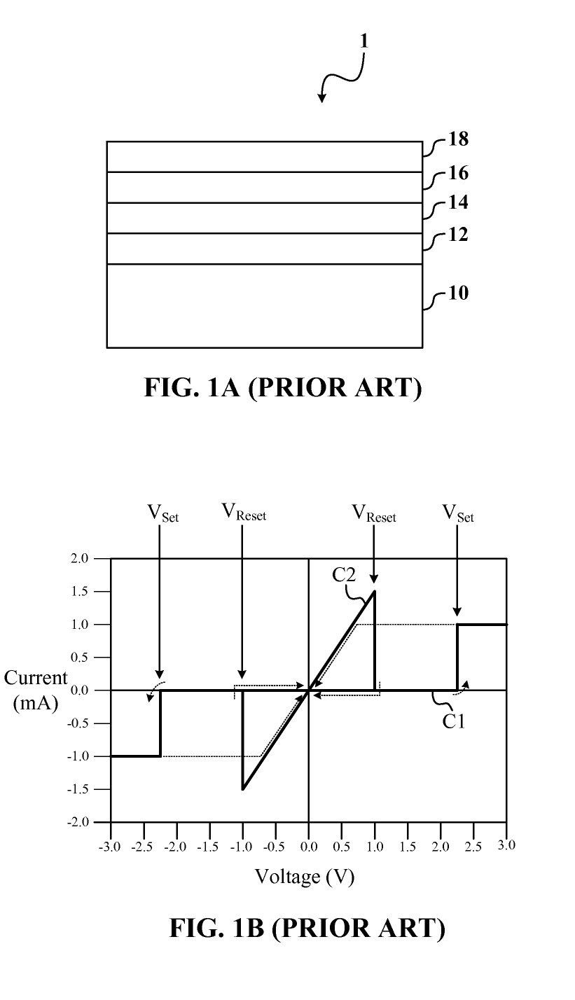

### DETAILED DESCRIPTION OF THE INVENTION

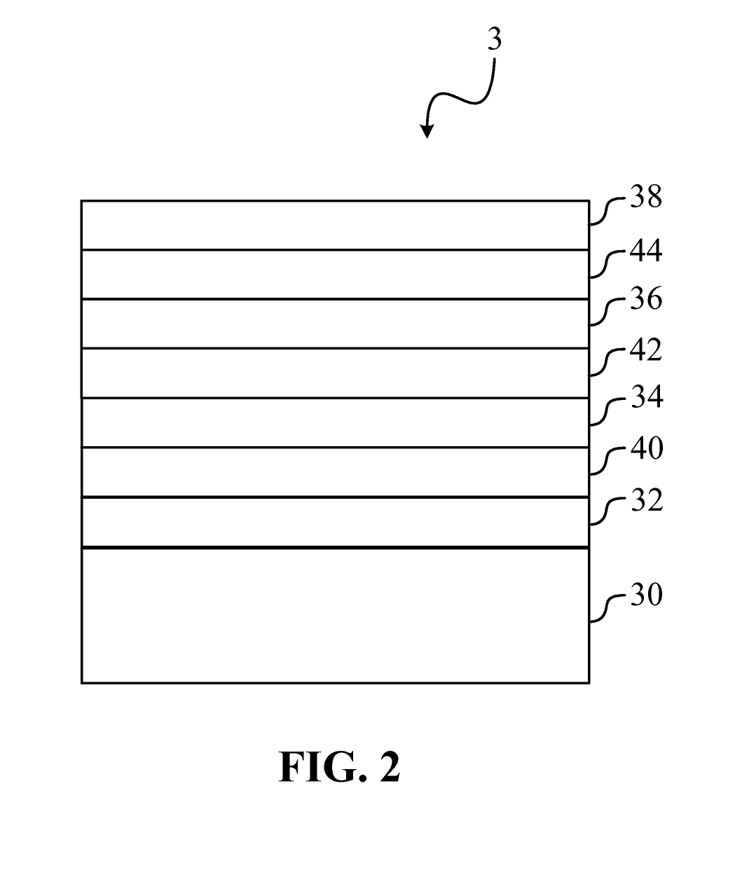

Please refer to FIG. 2. FIG. 2 is a cross-section view illustrating a memory device 3 according to an embodiment of the invention. As shown in FIG. 2, the memory device includes a substrate 30, an insulator layer 32, a first conducting layer 34, a resistor layer 36 and a second conducting layer 38. The insulator layer 32 is formed on the substrate 30. The first conducting layer 34 is formed on the insulator layer 32. The resistor layer 36 is formed on the first conducting layer 34. And, the second conducting layer 38 is formed on the resistor layer 36.

In the embodiment, the substrate 30 can be a silicon substrate, a silicon carbide substrate, or other similar substrates. The insulator layer 32 can be a silicon dioxide film whose thickness is within a range between 100 nm and 600 nm or other similar structures. The first conducting layer 34 can be a platinum film whose thickness is within a range between 10 nm and 600 nm or other similar structures. The second conducting layer 38 can be a platinum film whose thickness is within a range between 10 nm and 600 nm or other similar structures. It is notable that the resistor layer 36 adopted in the invention is a CaCu₃Ti₄O₁₂ film whose thickness is within a range between 20 nm and 1000 nm. The switching voltage of the CaCu₃Ti₄O₁₂ film is lower than that of the general used materials, thus the CaCu₃Ti₄O₁₂ film can greatly comply with the requirement of low-voltage electric products.

Beside, the second conducting layer 38 can be made of Pt, Cu, Ti, Ta, Ru, or Mo. The switching voltage of the memory device 3 can be modulated by using second conducting layers with different metals.

In a practical application, because the stickiness between the platinum film of the first conducting layer 34 and the silicon dioxide film of the insulator layer 32 is not good, the memory device 3 can further include a third conducting layer 40 between the insulator layer 32 and the first conducting layer 34 to increase the stickiness between the platinum film and the silicon dioxide film. In the embodiment, the third conducting layer 40 can be a titanium film whose thickness is within a range between 10 nm and 600 nm.

In addition, with different adopted materials of the second conducting layer 38, the memory device 3 can further include a first interfacial layer 42 with appropriate materials between the first conducting layer 34 and the resistor layer 36 and a second interfacial layer 44 with appropriate materials between the resistor layer 36 and the second conducting layer 38, so as to increase the stickiness of the resistor layer 36, the first conducting layer 34, and the second conducting layer 38, and to prevent the ingredients in the resistor layer 36 from diffusing to the first conducting layer 34 and the second conducting layer 38. Further, it can also prevent additional leakage electricity, so as to increase the reliability of the memory device 3.

In the embodiment, the invention mainly adopts the CaCu₃Ti₄O₁₂ film to form the resistor layer of the memory device. The switching voltage of the CaCu₃Ti₄O₁₂ film is lower than that used in prior arts, thus the CaCu₃Ti₄O₁₂ film can greatly comply with the requirement of low-voltage electric products. Moreover, the switching voltage of the memory device can be moderated by adequately adjusting the metals included in the second conducting layer. And, under the arrangement of the third conducting layer, the first interfacial layer, and the second interfacial, the reliability and the safety of the memory device can be promoted.

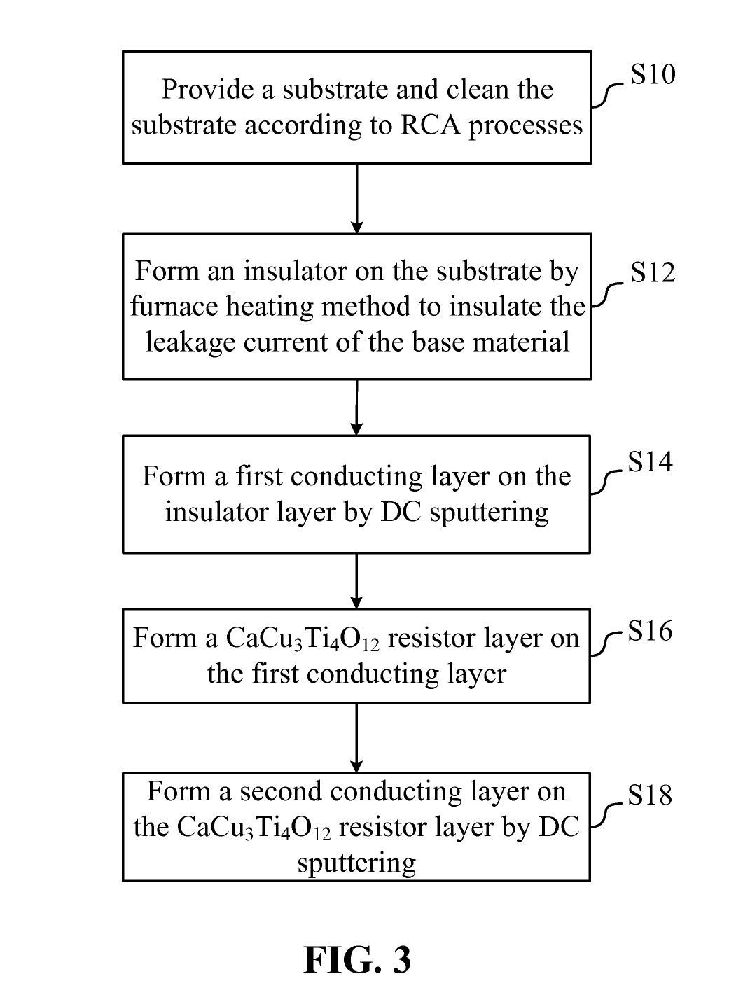

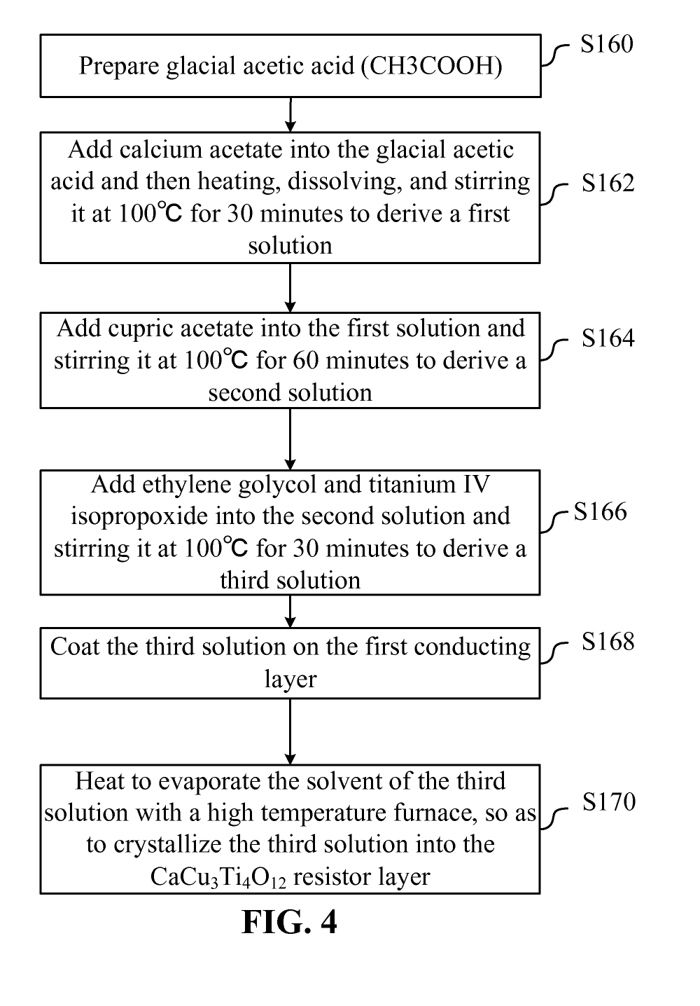

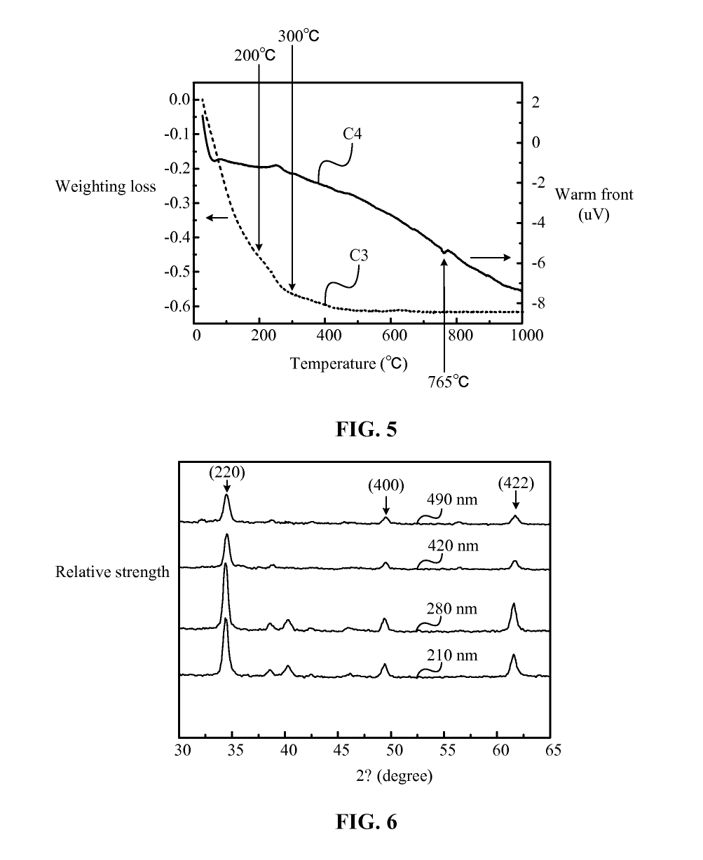

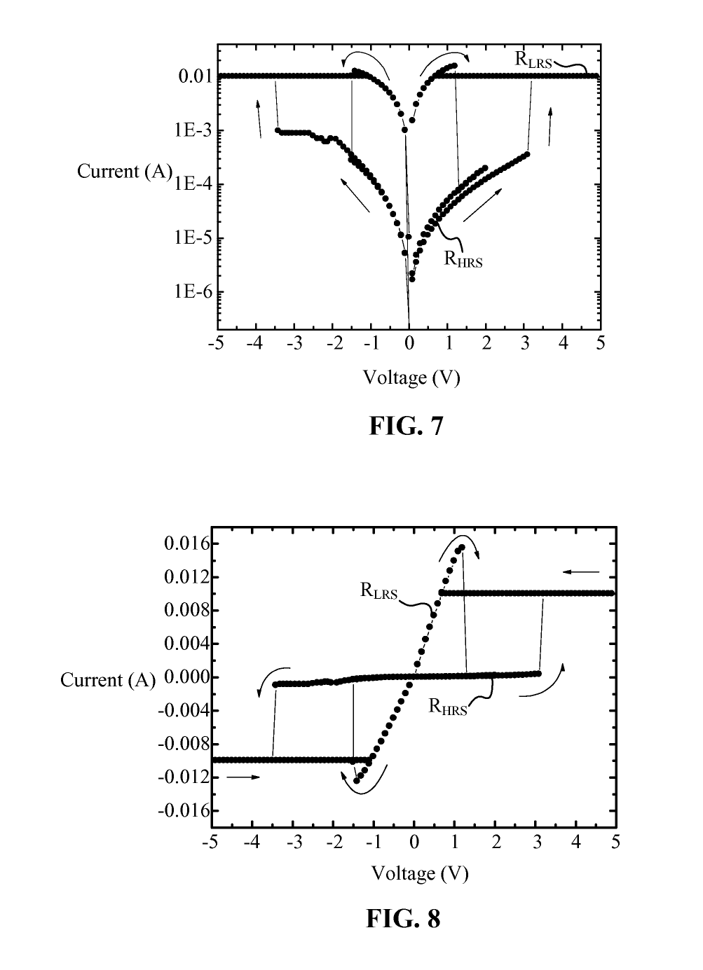

Please refer to the FIG. 3. FIG. 3 is a flow chart showing a method of manufacturing a memory device according to an embodiment of the invention. As shown in FIG. 3, firstly, step S10 is performed to provide a substrate and clean the substrate according to RCA processes. It needs to be explicated that the RCA processes are a silicon wafer cleaning technology developed by American company-RCA, which was applied in manufacturing in RCA devices in 1965 and published in 1970. The RCA processes can be divided in two steps: wet oxidation process and complexation process. The RCA processes are well known in prior arts which can be easily achieved, so they will not be described in detail here.

As followed, step S12 is performed to form an insulator on the substrate by furnace heating method to insulate the leakage current of the base material. Afterwards, step S14 is performed to form a first conducting layer on the insulator layer by DC sputtering. Then, step S16 is performed to form a CaCu₃Ti₄O₁₂ resistor layer on the first conducting layer. Finally, step S18 is performed to form a second conducting layer on the CaCu₃Ti₄O₁₂ resistor layer by DC sputtering. It needs to be explicated that the material, the structure and the working principles of the memory device are the same as the memory device 3 in FIG. 2, so they will not be described in detail here.

In the embodiment, the invention utilizes the sol-gel method to form the CaCu₃Ti₄O₁₂ resistor layer on the first conducting layer, which not only has the advantages such as low cost, easy control of manufacturing, and adaptability for manufacturing films with large area but also have higher consistency than the general semiconductor processes. So, the costs can be saved and the reliability of products can be promoted. It needs to be explicated that the way to form the CaCu₃Ti₄O₁₂ resistor layer of the invention is not limited to the sol-gel method.

Please refer to the FIG. 4. FIG. 4 is a flow chart of forming a CaCu₃Ti₄O₁₂ resistor layer on the first conducting layer by utilizing sol-gel process. As shown in FIG. 4, firstly, step S160 is performed to prepare glacial acetic acid (CH₃COOH). Next, step S162 is performed to add calcium acetate (Ca(CH₃COO)₂) into the glacial acetic acid and then heat, dissolve, and stir it at 100° C. for 30 minutes to derive a first solution. Afterwards, step S164 is performed to add cupric acetate (Cu(CH₃COO)₂)) into the first solution and then stir it at 100° C. for 60 minutes to derive a second solution. After that, step S166 is performed to add a ethylene golycol (C₂H₆O₂) and a titanium IV isopropoxide (TiC₁₂H₂₈O₄) into the second solution and then stir it at 100° C. for 30 minutes to derive a third solution. As followed, step S168 is performed to coat the third solution on the first conducting layer. Finally, step S170 is performed to evaporate the solvent of the third solution by heating the high temperature furnace, so as to crystallize the third solution into the CaCu₃Ti₄O₁₂ resistor layer. Herein, the thickness of the CaCu₃Ti₄O₁₂ resistor layer can be adjusted by the density of the solutions and times of coating.

The characteristics of the CaCu₃Ti₄O₁₂ resistor layer and sol-gel method will be further explained below.

Please refer to the FIG. 5. FIG. 5 is a thermo-gravimetric analysis diagram of the produced third solution. As shown in FIG. 5, it can be known that various kinds of volatile substances in the second solution can be removed between 200° C. and 400° C. according to curve C3 obtained by a thermo-gravity analyzer (TGA). In addition, it can be known that the second solution starts to grow CaCu₃Ti₄O₁₂ compound at 765° C. according to the curve C4 obtained by a differential scanning calorimeter. The thermo-gravity analyzer and the scanning calorimeter are well known in prior arts, so they will not be described in detail here.

Please refer to the FIG. 6. FIG. 6 is an X-ray diffraction pattern diagram showing CaCu₃Ti₄O₁₂ films with different thicknesses under the condition that the heat treatment temperature is 800° C. and the processing period is 30 minutes. As shown in FIG. 6, the X-ray diffraction pattern of CaCu₃Ti₄O₁₂ films whose thickness respectively are 490 nm, 420 nm, 280 nm, and 210 nm are demonstrated. It can be known that except (220), the lattice directions of the CaCu₃Ti₄O₁₂ film also include (400) and (422), which shows that the resistor layer of the CaCu₃Ti₄O₁₂ film is polycrystalline. The X-ray diffraction pattern diagram is well known in prior arts, so it will not be described in detail here.

Please refer to the FIG. 7. FIG. 7 is a schematic diagram illustrating the relationship between the voltage and the current of the memory device according to the invention. As shown in FIG. 7, the memory device of the invention has two different resistance values. The transition magnification between the high resistance state (R_{HRS}) and the low resistance state (R_{LRS}) can reach up to 500 times, and the threshold voltage is under 3.3 V. Furthermore, the result shows that in the direct of positive bias voltage, the current increases as the voltage increases, and the current hurriedly decreases at 3.3 V. That is to say, the memory device of the invention can utilize DC bias voltage to change the resistance value to achieve the goal of memorizing, and the operation of changing resistance values is repeatable.

Please refer to FIG. 8. FIG. 8 is a schematic diagram illustrating the relationship between the bias voltage and the leakage current of the memory device according to the invention. As shown in FIG. 8, it is clear that the memory device of the invention has two different resistance values which respectively represent the high resistance state and the low resistance state, and the threshold voltage exists between the bias voltages of 1.5 V and 3.3 V. Since the difference between them is easy to be distinguished, the requirement of the resistive memory devices can be easily achieved.

Compared with the prior art, the memory device provided by the invention takes the CaCu₃Ti₄O₁₂ film as the material of resistor layers. The switching voltage of the material is lower than that of the resistor layer of general resistive memory devices which comply with the requirement of general low-voltage electric products. Besides, the invention adopts sol-gel method to form the resistor layer, which not only has advantages of low cost and easy control of manufacturing, but also is appropriate to manufacture films with large area. Because of having the higher compatibility than general semiconductor methods, the invention can save the costs and promote the reliability of products at the same time. Moreover, the ratio of the switching voltage and the resistance value can be adjusted after utilizing different electrode material, so as to prompt the electrical performance of memory devices and meet with the requirements of practice utility.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A memory device, comprising:
a substrate;
an insulator layer formed on the substrate;
a first conducting layer formed on the insulator layer;
a CaCu₃Ti₄O₁₂ resistor layer formed on the first conducting layer; and
a second conducting layer formed on the resistor layer.

2. The memory device of claim 1, wherein the substrate is a silicon substrate or a silicon carbide substrate.

3. The memory device of claim 1, wherein the insulator layer is a silicon dioxide film whose thickness is within a range between 100 nm and 600 nm.

4. The memory device of claim 1, wherein the first conducting layer is a platinum film whose thickness is within a range between 10 nm and 600 nm.

5. The memory device of claim 1, wherein the thickness of the CaCu₃Ti₄O₁₂ resistor layer is within a range between 20 nm and 1000 nm.

6. The memory device of claim 1, wherein the second conducting layer is made of one material selected from a group consisting of Pt, Cu, Ti, Ta, Rb, and Mo.

7. The memory device of claim 6, wherein the second conducting layer is a platinum film whose thickness is within a range between 10 nm and 600 nm.

8. The memory device of claim 1, further comprising a third conducting layer which is between the insulator layer and first conducting layer.

9. The memory device of claim 8, wherein the third conducting layer is a platinum film whose thickness is within a range between the 10 nm and 600 nm.

10. The memory device of claim 1, further comprising a first interfacial layer and a second interfacial layer, the first interfacial layer being between the first conducting layer and the CaCu₃Ti₄O₁₂ resistor layer, and the second interfacial layer being between the CaCu₃Ti₄O₁₂ resistor layer and the second conducting layer.

11. A method of manufacturing a memory device comprising the steps of:
(a) providing a substrate;
(b) forming an insulator layer on the substrate;
(c) forming a first conducting layer on the insulator layer;
(d) forming a CaCu₃Ti₄O₁₂ resistor layer on the first conducting layer; and
(e) forming a second conducting layer on the CaCu₃Ti₄O₁₂ resistor layer.

12. The method of claim 11, wherein the substrate is a silicon substrate or a silicon carbide substrate, and step (a) further comprises the step of:
cleaning the substrate by RCA method.

13. The method of claim 11, wherein the insulator layer is a silicon oxide film whose thickness is within a range between 100 nm and 600 nm, and step (b) is performed to form the insulator layer on the substrate by furnace heating method.

14. The method of claim 11, wherein the first conducting layer is a platinum film whose the thickness within a range between 10 nm and 600 nm, and step (c) is performed to form the first conducting layer on the insulator layer by DC sputtering.

15. The method of claim 11, wherein the thickness of the CaCu₃Ti₄O₁₂ resistor layer is within arrange between 20 nm and 1000 nm.

16. The method of claim 11, wherein the second conducting layer is formed by one selected from a group consisting of Pt, Cu, Ta, Rb, and Mo, and step (e) is performed to form the second conducting layer on the CaCu₃Ti₄O₁₂ resistor layer by DC sputtering.

17. The method of claim 16, wherein the second conducting layer is a platinum film whose thickness is within a range between 10 nm and 600 nm.

18. The method of claim 11, wherein step (d) further comprises the steps of:
preparing glacial acetic acid;
adding calcium acetate into the glacial acetic acid and then heating, dissolving, and stirring it at 100° C. for 30 minutes to derive a first solution;
adding cupric acetate into the first solution and stirring it at 100° C. for 60 minutes to derive a second solution;
adding ethylene golycol and titanium IV isopropoxide into the second solution and stirring it at 100° C. for 30 minutes to derive a third solution;
coating the third solution on the first conducting layer; and
heating to evaporate the solvent of the third solution by heating the high temperature furnace, so as to crystallize the third solution into the CaCu₃Ti₄O₁₂ resistor layer.

19. The method of claim 11, further comprising the step of:
forming a third conducting layer on the insulator by DC sputtering.

20. The method of claim 19, wherein the third conducting layer is a Ti film whose thickness is within a range between 10 nm and 600 nm.

21. The method of claim 11, further comprising the step of:
forming a first interfacial layer on the first conducting layer.

22. The method of claim 11, further comprising the step of:
forming a second interfacial layer on the resistor layer.
